(19) United States
(12) Patent Application Publication
(10) Pub. No.: US 2006/0099790 A1
(43) Pub. Date: May 11, 2006

(54) Method of implanting at least one solder bump on a printed circuit board

(76) Inventors: Cheng-Yuan Lin, Taoyuan Hsien (TW); Te-Chang Huang, Taoyuan Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/972,459

(22) Filed: Oct. 26, 2004

(51) Int. Cl. H01L 21/44

(52) U.S. Cl. 438/612

(57) ABSTRACT

A method of implanting at least one solder bump on a surface of a printed circuit board (PCB) on which at least one soldering pad is exposed since the solder bump intended to be formed thereon is missing is described. The method comprises the steps of: first, forming at least one solder bump for mating with its exposed soldering pad. Then, coating a layer of flux on the surface of the PCB and the exposed soldering pad. Transplanting the solder bump onto the exposed soldering pad. Finally, reflowing the solder bump and clearing the layer of flux from the PCB. In this manner, the solder bump is made up for on the PCB.

### BACKGROUND OF THE INVENTION

1. Field of Invention

The present invention relates to a manufacturing method of a printed circuit board (PCB), and particularly to a method of implanting at least one solder bump on a PCB pad.

2. Related Art

A printed circuit board (PCB) has conductive lines formed on its surface and the conductive lines are generally made of copper (Cu). A solder resist is generally formed to cover and protect the conductive lines and a plurality of copper soldering pads are thus formed and exposed, which are used to fix surface mount devices (SMDs) intended to be mounted, such as BGA and QFA devices, on the PCB by soldering. However, it is not easy to form an alloy of tin and copper in a quick soldering process. In this case, a precoated tin solder is generally first formed on the copper soldering pad so that the copper soldering pad and the precoated tin solder may form an alloy in a quick process and a good soldering purpose is thus accomplished. Particularly, if the solder is made of the same material as that of the precoated solder, the soldering may be further assured with better reliability.

In the case of soldering a flip chip device or BGA (ball grid arrays) bumps, and enhancing the alignment between the flip chip device or the BGA and the PCB, the precoated solder on the PCB are formed with an increased height and like a ball in outline which are like bumps formed on a bottom of the flip chip device or of the BGA. For a high-density device and wires-mounted PCB, this technology of formation of the solder bumps can be critical and necessary.

For the present, stencil printing technology is a widely used method in forming the solder bumps. In performing the stencil printing method, a plurality of hollowed holes are formed and each of which corresponds to a copper soldering pad among a plurality of copper soldering pads on the PCB. Then, the stencil is aligned and positioned on the PCB so that the copper soldering pads are exposed in the holes of the stencil. Then, paste solder are filled up in the holes by a scraper. Finally, a reflow process is subject to the PCB so as to turn the paste solder in the holes to be the desired solder bumps. When the stencil is separated from the PCB, the solder bumps are thus formed for fixing of SMDs on the PCB.

However, some holes of the stencil might not be filled up with paste solder due to unsound filling process, which causes that copper soldering pads of the same number as that of the holes without being filled are each not formed thereon with a solder bump. Since there are not any solder bump mated with the copper soldering pads in dimension and outline sold in the market, the PCB corresponding to the copper soldering pads will be discarded owing to a defect resulted from the missing of the solder bumps and the loss is correspondingly caused.

### SUMMARY OF THE INVENTION

It is, therefore, an object of the present invention to provide a method of implanting at least one solder bump on a printed circuit board (PCB) to resolve the problem existed in the prior technology that the PCB has to be discarded once the solder bump is missing therefrom.

To achieve the above object, the method of implanting at least one solder bump on a printed circuit board (PCB) according to the present invention comprises: first, forming at least one solder bump for mating with its corresponding exposed soldering pad on the PCB. Then, coating a viscous liquid, such as a layer of flux, on the surface of the PCB and on the exposed soldering pad. Transplanting the solder bump onto the soldering pad. Finally, apply a heat process to the solder bump, such as applying reflow treatments to the solder bump and then clearing the layer of flux from the PCB so that the solder bump is made up for on the PCB. Therefore, a PCB may not be discarded for lacking the solder bump formed on the soldering pad and cost of the PCB is greatly reduced.

### BRIEF DESCRIPTION OF THE DRAWINGS

The invention will become more fully understood from the detailed description given hereinbelow illustration only, and thus are not limitative of the present invention, and wherein:

FIGS. 1 to 4 illustrate a prior process of forming solder bumps on a printed circuit board (PCB) by a stencil printing method; and

FIGS. 5 to 11 are diagrams illustrating a preferred embodiment of a method of implanting a solder bump on a surface of a PCB according to the present invention.

### DETAILED DESCRIPTION OF THE INVENTION

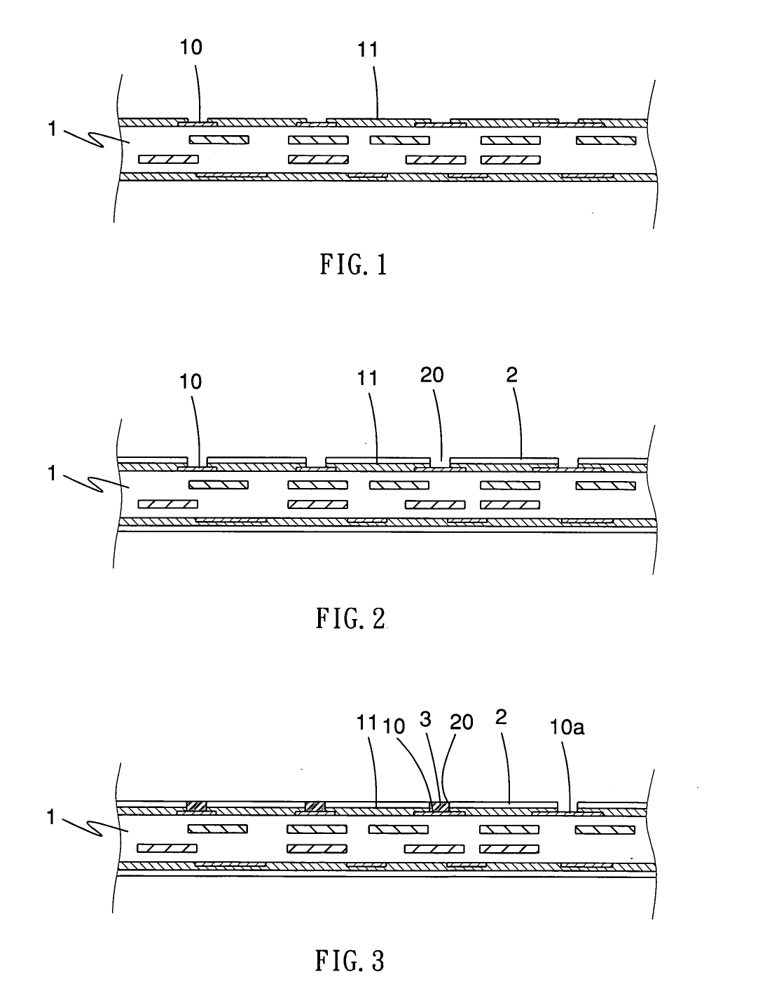

Referring to FIG. 1, a multiple layer printed circuit board (PCB) is illustrated therein. A solder resist layer is formed on copper-made conductive lines on a surface of the PCB 1. Therefore, a plurality of copper soldering pads 10 and a solder resist layer 11 are formed on the PCB 1 and the plurality of copper soldering pads 10 are exposed with respect to the solder resist layer 11.

Referring to FIG. 2, it may be seen that a stencil 2, such as a steel stencil, is stacked onto the PCB 1. The stencil 2 has a plurality of holes 20 each corresponding to a mated soldering pad 10 so that each of the plurality soldering pads 10 is exposed from the mated hole 20 of the stencil 2.

Referring to FIG.3, a process of filling up the plurality of holes 20 of the stencil 2 by paste solder 3 by means of a scraper is illustrated.

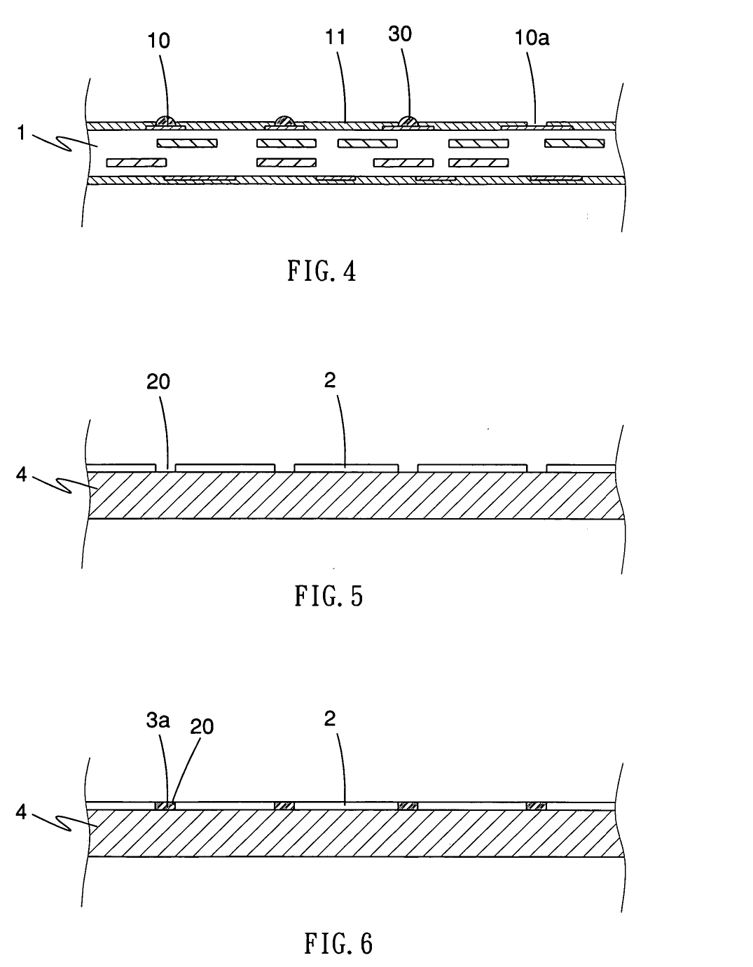

Referring to FIG. 4, the PCB 1 after being subjected to a heat process, such as reflowing and being separated with the stencil 2 is illustrated therein. Each paste solder 3 in the corresponding hole 20 of the stencil 2 is formed as a solder bump 30 shaped as a ball due to the melting effect and a strain occurred therein.

It is to be particularly noted that the holes 20 might be not filled up with the paste solder 3 corresponded due to an unsound soldering process. In this described case, one hole 20 is not filled up with the paste solder 3 and thus the PCB 1 has a soldering pad 10a exposed after the stencil 2 is removed from the PCB 1. Namely, one solder bump 30 is missing to the soldering pad 10a, referring to the FIG. 3.

In response to this problem, the present invention sets forth a method of implanting at least one missing solder bump 30 on the exposed soldering pad 10a on the PCB 1 and the method is illustrated in FIGS. 5 to 7. In the embodiment corresponding to FIGS. 5 to 7, the above case where only one solder bump 30 is missing is taken to be described.

Referring to FIG. 5, a glass plate 4 is provided and the stencil 2 used to form the solder bumps 30 is stacked onto the glass plate 4.

Next referring to FIG. 6, paste solder 3a is filled up in each of the holes 20 of the stencil 2 by a scraper.

Next, reflowing the paste solder 3a in the holes 20 to form solder bumps 30a.

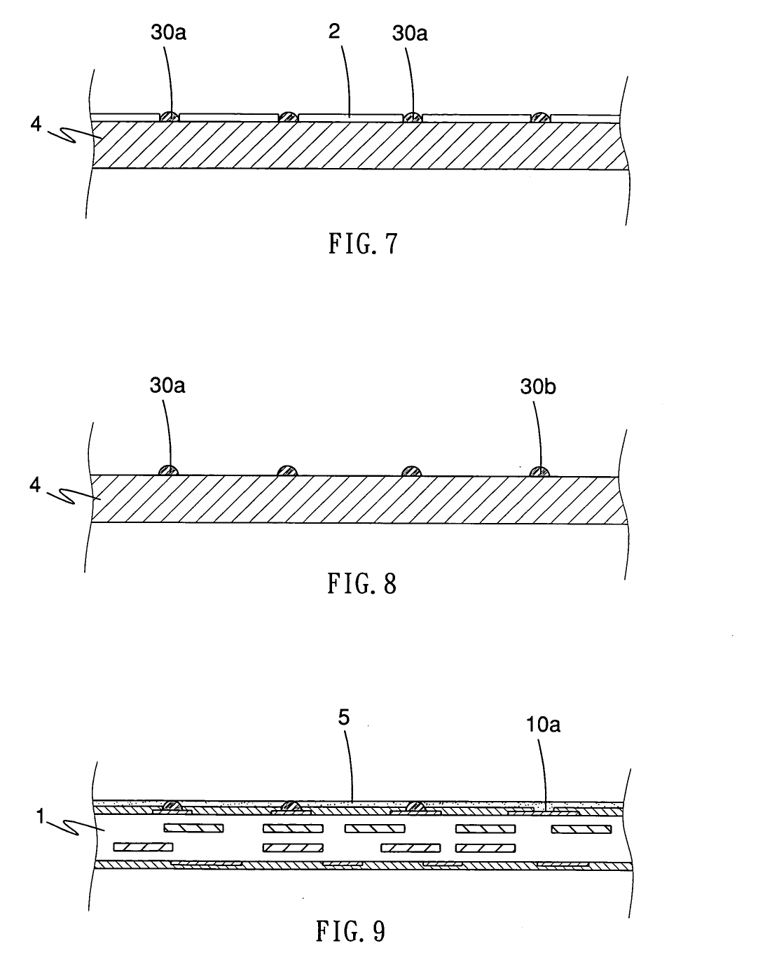

Referring to FIG. 8, removing the stencil 2 from the glass plate 4 and the solder bumps 30a, 30b are left on the glass plate 4. On the glass plate 4, the solder bump 30b in the figure, is mated in dimension and outline with the soldering pad 10a because the stencil 2 is the original used stencil 2 for forming solder bumps 30 on the PCB 1. The solder bumps 30a, 30b are not tightly connected with a surface of the glass plate 4 attached therewith and thus the solder bumps 30a, 30b may be easily removed completely from the glass plate 4. As a matter of fact, any material of substrate which may not form a tight connection with the formed solder bumps 30a, 30b may be suitable to be used in the process shown in FIGS. 7 and 8.

Next, coating a layer of flux 5 onto the surface of the PCB 1 as shown in FIG. 9, wherein the layer of flux 5 covers the soldering pad 10a. In a practical process, the PCB 1 is preferably covered entirely by the layer of flux 5.

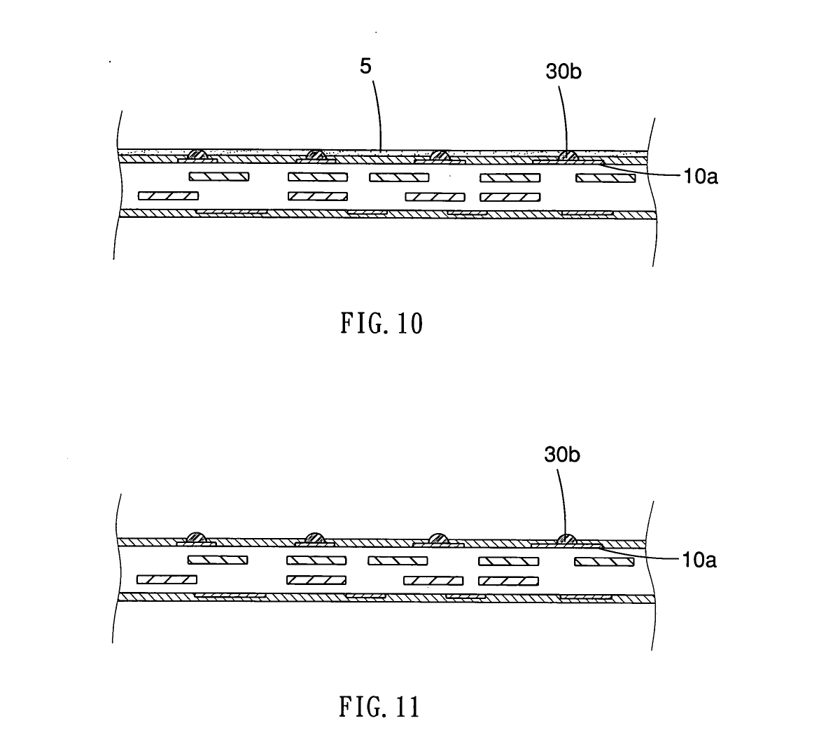

Then, pick the solder bump 30b from the glass plate 4 by a needle (not shown) and deliver the solder bump 30b onto the soldering pad 10a, which is shown in FIG. 10. When the solder bump 30b is positioned on the soldering pad 10a, the solder bump 30b sinks into the layer of flux 5 and stays close to the soldering pad 10a owing to a greater specific weight than that of the layer of flux 5. Further, since the layer of flux 5 is viscous, the solder bump 30b may temporarily cling to the soldering pad 10a and not move at random.

Thereafter, reflowing the PCB 1 so that the solder bump 30b is soldered to the soldering pad 10a. During the reflowing process, the solder bump 30b still maintains its balled outline due to the strain therein.

Finally, clearing the layer of flux 5 and the PCB 1 at this time is like the illustration in FIG. 11. It is to be noted that the soldering pad 10a has been implanted with the solder bump 30b and each soldering pad on the PCB 1 has been formed with a solder bump.

It is to be particularly indicated that the stencil 2 forming the solder bumps 30a by stacking onto the PCB 1 is directly used in forming the solder bumps 30a by stacking onto the glass plate 4 and thus the purpose of cost saving is achieved. Also, it is well guaranteed that there is the solder bump 30b mated in dimension and outline with the soldering pad 10a. That is, the soldering pad 10a may absolutely be implanted with the solder bump 30b, among the solder bump 30a on the glass plate 4 which has desirable dimension and outline with respect to the soldering pad 10a.

From the foregoing description, any person skilled in the art may be sufficiently taught that the method set forth in this invention may actually resolve the long-existed problem that a PCB may not be used any more once missing solder bumps are occurred on the PCB.

While the preferred embodiments of the present invention have been set forth for the purpose of disclosure, modifications of the disclosed embodiments of the present invention as well as other embodiments thereof may occur to those skilled in the art. Accordingly, the appended claims are intended to cover all embodiments which do not depart from the spirit and scope of the present invention.

We claim:

1. A method of implanting at least one solder bump on a surface of a printed circuit board (PCB) having at least one exposed soldering pad lacking for the at lease one solder bump, the method comprising the steps of:
forming the at least one solder bump for mating with the at least one exposed soldering pad;
coating a viscous liquid on the PCB and the viscous liquid covering the at least one exposed soldering pad;
transplanting the at least one solder bump onto the at least one exposed soldering pad;
heating the at least one solder bump so that the at least one solder bump is soldered to the at least one exposed soldering pad; and
clearing the viscous liquid from the PCB.

2. A method of implanting at least one solder bump on a surface of a printed circuit board (PCB) having a solder resist layer and at least one soldering pad exposed from the solder resist layer and lacking for the at least one solder bump, the method comprising the steps of:
forming the at least one solder bump for mating with the at least one soldering pad;
coating a layer of flux on the PCB and the layer of flux covering the at least one soldering pad;
transplanting the at least one solder bump onto the at least one exposed soldering pad;
reflowing the PCB so that the at least one solder bump is soldered to the at least one exposed soldering pad; and
clearing the layer of flux from the PCB.

3. The method as claimed in claim 1, wherein the step of forming the at least one solder bump comprises the steps of:
providing a glass plate;
stacking a stencil having at least one hole mated with the at least one soldering pad onto the glass plate;
filling up the at least one hole with paste solder by a stencil printing method;
reflowing the paste solder so that the paste solder forms the at least one solder bump; and
removing the stencil from the glass plate.

4. The method as claimed in claim 1, wherein the step of transplanting the at least one solder bump comprises the steps of:
providing a needle; and
picking the at least one solder bump by the needle and delivering the at least one solder bump to the at least one exposed soldering pad.

5. The method as claimed in claim 2, wherein the step of forming the at least one solder bump comprises the steps of:
providing a glass plate;
stacking a stencil having at least one hole mated with the at least one soldering pad onto the glass plate;
filling up the at least one hole with paste solder by a stencil printing method;
reflowing the paste solder so that the paste solder forms the at least one solder bump; and
removing the stencil from the glass plate.

6. The method as claimed in claim 2, wherein the step of transplanting the at least one solder bump comprises the steps of:
providing a needle; and
picking the at least one solder bump by the needle and delivering the at least one solder bump to the at least one soldering pad.

7. The method as claimed in claim 3, wherein the step of transplanting the at least one solder bump comprises the steps of:
providing a needle; and
picking the at least one solder bump by the needle and delivering the at least one solder bump to the at least one exposed soldering pad.

8. The method as claimed in claim 5, wherein the step of transplanting the at least one solder bump comprises the steps of:
providing a needle; and
picking the at least one solder bump by the needle and delivering the at least one solder bump to the at least one soldering pad.
